(19) United States
(12) Patent Application Publication
(10) Pub. No.: US 2013/0307562 A1
(43) Pub. Date: Nov. 21, 2013

(54) SYSTEMS AND METHODS FOR FFT-BASED MICROWAVE DISTANCE SENSING FOR A PLUMBING FIXTURE

(71) Applicant: Shanghai Kohler Electronics, Ltd., Shanghai (CN)

(72) Inventors: Zhongmin Chen, Shanghai (CN); Pengcheng Gao, Shanghai (CN)

(21) Appl. No.: 13/895,996

(22) Filed: May 16, 2013

(30) Foreign Application Priority Data
May 16, 2012 (CN) 201210152830.7

(51) Int. Cl. G01R 27/28

(52) U.S. Cl. CPC G01R 27/28
USPC 324/637

(57) ABSTRACT

Systems and methods for detecting a position of an object relative to a plumbing fixture are provided. A described method includes emitting a microwave detection signal toward a moving object, receiving an echo-wave signal reflected from the moving object, and superimposing the microwave detection signal and the echo-wave signal to produce a superimposed time domain signal. The method further includes performing a Fast Fourier Transformation on the time domain signal to generate a frequency domain signal, integrating the frequency domain signal, and actively adjusting a result of the integration by subtracting a predetermined amount from the result. The predetermined amount is at least one of: a volume contribution amount and an interference contribution amount. The method further includes determining a position of the moving object relative to the plumbing fixture by comparing the adjusted integration result with a distance standard curve.

### CROSS-REFERENCE TO RELATED PATENT APPLICATIONS

The present application claims the benefit of and priority to Chinese Patent Application No. 201210152830.7, filed May 16, 2012, under 35 U.S.C. §119. The entirety of Chinese Patent Application No. 201210152830.7 is incorporated by reference herein.

### TECHNICAL FIELD

The present invention relates generally to systems and methods for detecting movement modes of an object, and more particularly to a method and apparatus for Fast Fourier Transformation (FFT)-based microwave detection.

### BACKGROUND

Prior art microwave detection methods and devices present many technical problems to be solved. This is especially true for microwave detection methods and devices used in toilets and bathrooms. Because bathrooms are relatively small and the movement speeds of bathroom objects are relatively slow, it is generally required that the movement state (e.g., distance, position, etc.) of a bathroom object be determined with a relatively high accuracy. However, prior art microwave sensors are typically hidden (e.g., behind or in a wall), resulting in a relatively poor accuracy in detecting an object's movement state.

Moreover, the signal output by typical microwave sensors is constrained by its power and consequently has relatively small signal amplitude. Because signal amplitude reflects the distance between the object and the sensor, a relatively small signal amplitude increases the potential for interference (e.g. power line interference, cell phone signal interference, etc.). Furthermore, current microwave detection technologies only compare the amplitude of the signal output by the sensor at a certain time with a pre-set threshold value without generating a distance value.

Prior art microwave detection methods and devices typically have a low accuracy in determining distances and an inefficient filtering of interference signals. These shortcomings can cause current microwave detection devices to send incorrect signals and can result in faulty operation of bathroom equipment. A solution to the aforementioned problems is needed.

### SUMMARY

One implementation of the present disclosure is a FFT-based microwave detection method. The method includes transmitting a microwave detection signal to a moving object, receiving an echo-wave signal of the moving object, and superimposing the microwave detection signal and the echo-wave signal as a time domain analog signal. The method further includes sampling the time domain analog signal at a sampling frequency of f and performing analog-digital conversion to obtain a discrete time domain digital signal. The method further includes performing FFT on continuous P discrete time domain digital signals at a certain time interval of Δt to obtain a frequency domain signal and integrating the amplitude of the frequency domain signal within a specific frequency band to obtain an integration sum SumA. In some embodiments, the specific frequency band is determined according to the movement characteristics of the moving object. The method further includes accumulating the integration sums (e.g., multiple SumAs of previous N times including current time) to obtain an accumulation sum SUM_{accum} and comparing SUM_{accum} with a pre-stored “Accumulation Sum Distance Standard Curve” to obtain current distance of the moving object.

Another implementation of the present disclosure is a FFT-based microwave detection apparatus. The detection apparatus includes a microwave sensor which transmits a microwave detection signal to a moving object, receives an echo-wave signal of the moving object, superimposes the microwave detection signal and the echo-wave signal as a time domain analog signal, and outputs the time domain analog signal. The detection apparatus further includes a sampling and analog-digital converter which receives the time domain analog signal from the microwave sensor, samples the time domain analog signal at a sampling frequency of f, and performs analog-digital conversion to obtain a discrete time domain digital signal. The detection apparatus further includes a FFT device which receives the discrete time domain digital signal from the sampling and analog-digital converter, and performs FFT on continuous P discrete time domain digital signals at a certain time interval of Δt to obtain a frequency domain signal. The detection apparatus further includes a movement state determination device which performs integration of the amplitude of the frequency domain signal within a specific frequency band to obtain an integration SumA, accumulates a plurality of integration sums (e.g., multiple SumAs) to obtain an accumulation sum ^{SUM}_{accum}, and compares SUM_{accum} with the pre-stored “Accumulation Sum Distance Standard Curve” to obtain current distance of the moving object.

Advantageously, the accuracy provided by the present invention is 50% higher than traditional microwave detection technologies. Further, the present invention provides strong resistance to interference, particularly to power frequency interference and cell phone signal interference. Further, the present invention can be calibrated before delivery from the factory, which can compensate the non-uniformity of sensitivity of microwave sensors.

### BRIEF DESCRIPTION OF THE DRAWINGS

FIG. 1 is a flowchart of a process for FFT-based microwave detection, according to an exemplary embodiment.

FIG. 2 is drawing of an Accumulation Sum Distance Standard Curve, according to an exemplary embodiment.

FIG. 3 is a block diagram of a FFT-based microwave detection apparatus, according to an exemplary embodiment.

FIG. 4 is a graphical illustration of experimental data demonstrating the detection accuracy of prior art microwave detection devices, according to an exemplary embodiment.

FIG. 5 is a graphical illustration of experimental data demonstrating the improved detection accuracy the systems and methods described herein, according to an exemplary embodiment.

### DETAILED DESCRIPTION

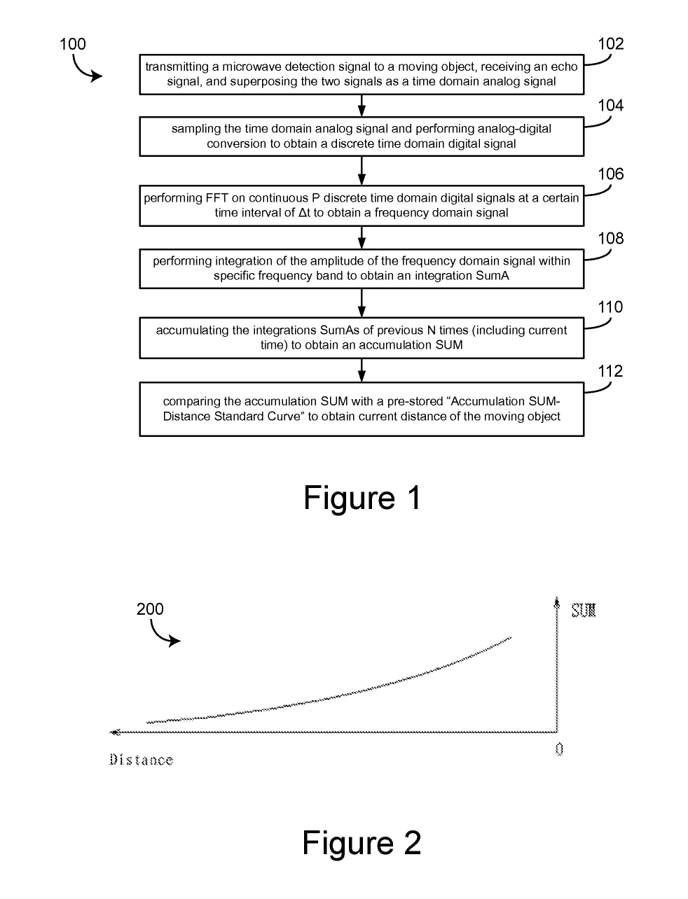

Referring to FIG. 1, a flowchart of a Fast Fourier Transform (FFT)-based microwave detection process 100 is shown, according to an exemplary embodiment. Process 100 is shown to include transmitting a microwave detection signal to a moving object, receiving an echo signal, and superimposing the two signals as a time domain analog signal (step 102). In some embodiments, the microwave detection signal may be transmitted to the moving object by a microwave sensor. The microwave detection signal may be reflected by the moving object and sent back to the microwave sensor as an echo signal. The microwave sensor may then superimpose the two signals to obtain and output a low frequency time domain analog signal.

Process 100 is shown to further include sampling the time domain analog signal and performing analog-digital conversion to obtain a discrete time domain digital signal (step 104). In some embodiments, the low frequency time domain analog signal is sampled continuously and converted to a time domain discrete digital signal. In some embodiments, the frequency f at which the low frequency time domain analog signal is sampled is determined according to the movement characteristics (e.g. velocity, movement direction) of the moving object. In some embodiments, the sampling frequency f is at least two times greater than the greatest frequency needed for detection.

Process 100 is shown to further include performing FFT on continuous P discrete time domain digital signals at a certain time interval of Δt to obtain a frequency domain signal (step 106). Step 106 may be performed on the time domain discrete signals after performing the aforementioned steps involving sampling and analog-digital conversion. The variable P may represent a number of time domain discrete digital signals on which the FFT is performed (e.g., P-point FFT). The frequency domain signal produced by the FFT may be a movement spectrum which indicates the distribution of the movement characteristics in the frequency domain. An amplitude A of the spectrum curve may represent the distance between the object and the sensor.

Still referring to FIG. 1, process 100 is shown to further include performing integration of the amplitude A of the frequency domain signal within a specific frequency band to obtain an integration sum SumA (step 108). The specific frequency band may be based on the range of frequencies represented in the movement spectrum curve. In some embodiments, the frequency band is between a first frequency and a second frequency. The first frequency may be no greater than the lowest frequency needed for detection. The second frequency is greater than the first frequency and, in some embodiments, is no smaller than the highest frequency needed for detection. The integration sum SumA may be obtained by summing the amplitudes A of the frequency domain signal at discrete frequency intervals within the frequency band.

Process 100 is shown to further include accumulating the integration sums (e.g., multiple SumAs) to obtain an accumulation sum SUM_{accum} (step 110). The accumulation sum SUM_{accum} may be calculated by adding the previous N integration sums, including the current integration sum SumA.

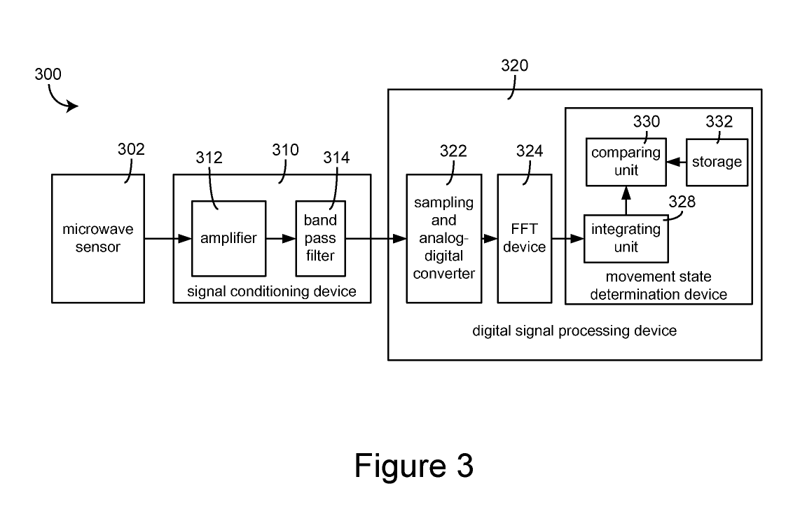

Process 100 is shown to further include comparing the accumulation sum SUM_{accum} with a pre-stored “Accumulation Sum Distance Standard Curve” to obtain current distance of the moving object (step 112). In some embodiments, the Accumulation Sum Distance Standard Curve is determined by a manufacturer and stored in a permanent or semi-permanent data storage device before the sensor is delivered from the factory. In other embodiments, the Accumulation Sum Distance Standard Curve is stored in a non-volatile data storage of the microwave detection apparatus as shown and described with reference to FIG. 3.

Referring now to FIG. 2, an Accumulation Sum Distance Standard Curve 200 is shown, according to an exemplary embodiment. Curve 200 may be obtained (e.g., determined, calculated, calibrated, set, etc.) by selecting a plurality of target distances (e.g., 2 m, 1.5 m, 1 m, 0.5 m, etc.) as calibration points. As an object moves at a conventional speed (e.g., 1 m/s for a human body), SUM_{accum} can be calculated at each of the target distances. The known target distances and calculated values for SUM_{accum} can be plotted as data points and Accumulation Sum Distance Standard Curve 200 can be obtained by interpolation between the data points.

In some embodiments, the amplitude of the echo-wave signal may be small and various sources of interference (e.g. power line interference, cell phone signal interference, etc.) may be present. To compensate for the interference, the signal outputted by the microwave sensor can be conditioned. The signal conditioning process may include amplifying and band pass filtering the echo-wave signal before performing sampling and analog-digital conversion. The signal can be amplified and interfering signals (e.g., “clutter signals”) can be filtered (e.g., using a band pass filter) to improve the accuracy of the subsequent processing steps. The lower and upper turning frequencies of the band pass filter (e.g., upper and lower limits defining the band pass range) may be determined according to the movement characteristics (e.g. velocity, movement direction) of the moving object. In some embodiments, the sampling frequency f is set at about three times of the upper turning frequency of the band pass filter. In some embodiments, the sampling frequency f is based on the required detection accuracy and/or in consideration of the amount of data processing required at various sampling frequencies.

In some implementations, the volume of the object can influence the amplitude of the signal output by the microwave sensor. Specifically, objects having larger volumes may result in amplitude signals having greater amplitudes. In some embodiments, the effect of object volume on the amplitude of the signal can be eliminated. For example, when obtaining (e.g., setting, generating, calibrating, etc.) Accumulation Sum Distance Standard Curve 200, a standard volume (e.g. for an adult person) can be selected. Because the volume difference among people is usually small, a standard volume can be selected easily. When generating curve 200, the accumulation sum SUM_{accum} of an object having the standard volume is measured and calculated as previously described. A much smaller object relative to the object having the standard volume is then selected and the accumulation SUM_{accum}_{_{—}}ₛₘₐₗₗ of the smaller object is measured and calculated. The volume contribution SUM_{accum}_{_{—}}ᵥₒᵢ to the accumulation sum SUM_{accum} of the standard volume object (e.g., an amount of SUM_{accum} which is solely a result of the object's larger volume) can be obtained by subtracting the accumulation sum of the smaller object SUM_{accum}_{_{—}}ₛₘₐₗₗ from the accumulation sum of the object having the standard volume SUM_{accum} (e.g., SUM_{accum}_{_{—}}ᵥₒᵢ=SUM_{accum}−SUM_{accum}_{_{—}}ₛₘₐₗₗ).

An adjusted Accumulation Sum Distance Standard Curve can be obtained by subtracting SUM_{accum}_{_{—}}ᵥₒₗ from each of the accumulation sums represented in curve 200. The adjusted curve can then be stored in a microwave sensor or a non-volatile data storage device as previously described and used in place of or in addition to curve 200. During actual detection, the volume contribution amount SUM_{accum}_{_{—}}ᵥₒₗ may be subtracted from the obtained actual accumulation sum SUM_{accum}, and the subtracted result can be compared with the adjusted Accumulation Sum Distance Standard Curve, thereby eliminating the influence of volume and obtaining more accurate distance measurements. Accumulation Sum Distance Standard Curve 200 can be adjusted as described above for different types of sensed objects (e.g. a human body, a ball, etc.).

Further, to improve accuracy and eliminate interference signals of some frequencies, an accumulation sum SUM_{accum}_{_{—}}_{static} can be measured and calculated for an object in a static state. In some embodiments, SUM_{accum}_{_{—}}_{static} is measured and calculated after obtaining Accumulation Sum Distance Standard Curve 200. SUM_{accum}_{_{—}}_{static} may be stored in a microwave sensor or a non-volatile data storage device as previously described. An adjusted Accumulation Sum Distance Standard Curve can be obtained by subtracting the interference signal contribution amount SUM_{accum}_{_{—}}_{static} from each of the accumulation sums represented in curve 200. During actual detection, the interference signal contribution amount SUM_{accum}_{_{—}}_{static} may be subtracted from the actual calculated accumulation sum SUM_{accum} of the object. The subtracted result (e.g., SUM_{accum}−SUM_{accum}_{_{—}}_{static}) can be compared with the adjusted Accumulation Sum Distance Standard Curve to obtain a current distance.

For example, consider a 10.525 GHz Doppler microwave sensor (e.g., as described in Chinese Patent Application No. 200910053657.3 titled “Microwave Doppler Sensing System Antenna” and Chinese Patent Application No. 200910052832.7 titled “Low-speed Microwave Detection System”). According to the Doppler principle, the relationship between the frequency of the “low frequency signal” Fₒᵤₜ output by the microwave sensor (e.g., the difference between the frequencies of the emitted and received signals) and the movement speed of a sensed moving object is described as shown in the following equation:

$${F}_{out} = 2 \cdot {V}_{m} \cdot \frac{{F}_{mv}}{C} \cdot cos ( θ )$$

where Vₘ is the movement speed of the object, Fₘᵥ is the microwave frequency emitted by the sensor (e.g., 10.525 GHz), C is the speed of light (i.e., 3×10⁸ m/s) and θ is the angle between the movement direction of the moving object and the direction of microwave emission by the sensor. For example, an angle of θ=0 would correspond to the direction of movement being the same as the direction of microwave emission by the sensor. In some embodiments, it is assumed that θ=0.

Applying the above values to the formula

$${F}_{out} = 2 \cdot {V}_{m} \cdot \frac{{F}_{mv}}{C} \cdot cos ( θ ) ,$$

the detected signal frequency Fₒᵤₜ can be calculated as a function of movement speed Vₘ. In some applications, as may be common in a bathroom setting, the movement speed Vₘ of the object is less than 2 m/s. When the movement speed Vₘ is 1 m/s, Fₒᵤₜ may be approximately 70 Hz (e.g.,

$${F}_{out} = 2 \cdot 1 \cdot \frac{10.525 \times {10}^{9}}{3 \times {10}^{8}} \cdot cos ( 0 ) \approx 70 ) .$$

When the movement speed Vₘ is 2 m/s, Fₒᵤₜ may be approximately 140 Hz (e.g.,

$${F}_{out} = 2 \cdot 2 \cdot \frac{10.525 \times {10}^{9}}{3 \times {10}^{8}} \cdot cos ( 0 ) \approx 140 ) .$$

In some embodiments, the signal output by the sensor is conditioned. The signal conditioning process may include amplifying and band pass filtering. The lower and upper turning frequencies of the band pass filter may be determined according to the movement characteristics (e.g. speed, direction) of the moving object. In some embodiments, the lower turning frequency of the band pass filter may be set to 10 Hz and the upper turning frequency thereof may be set to 350 Hz.

The conditioned signal may then be sampled and analog-digital converted to obtain a time domain discrete digital signal. In some embodiments, the signal sampling frequency f may be set to a value approximately three times the value of the upper turning frequency used by the band pass filter. For example, an upper turning frequency of 350 Hz may correspond to a sampling frequency f of approximately 1 kHz. Accordingly, the signal sampling period T (i.e., the inverse of the sampling frequency f) may be approximately 1 millisecond. Fast Fourier Transformation (FFT) may be performed on a number P of continuous discrete time domain digital signals at a time interval of Δt. In some embodiments, the values of P and Δt may be set based on the calculating capability (e.g., processing power) of the microwave sensor and the required accuracy of the final distance calculation. In some embodiments, P may be approximately 128 and Δt may be approximately 32 milliseconds. The FFT may produce a frequency domain signal between the spectrum of 0-500 Hz.

In some embodiments, integration is performed on selected frequency ranges in the frequency domain signal to avoid frequencies known to experience external interference. For example, a power line frequency may be known to be approximately 50 Hz or 60 Hz (100 Hz or 120 Hz after half-wave rectification). Cell phone signal interference frequency (e.g. for GSM cell phones) is usually 220 Hz. Therefore, integration may be performed on the amplitudes A of 4 Hz-92 Hz in the outputted spectrum after each FFT so as to avoid power line interference and cell phone signal interference. Integration sum SumA may be obtained by integrating the frequency domain signal between a first frequency (e.g., 4 Hz) and a second frequency (e.g., 92 Hz).

The integration sums (e.g., multiple SumAs) for the previous N times before current time may be accumulated to obtain an accumulation sum SUM_{accum}. In some embodiments, the value of N is selected according to the calculating capability of the microwave sensor and/or the required accuracy of the final distance measurement. In some embodiments, N=16, meaning that the previous 16 SumA s are added to calculate SUM_{accum}.

In order to avoid power line interference of 50 Hz or 60 Hz (100 Hz or 120 Hz after half-wave rectification) and GSM cell phone signal frequency interference (e.g., 220 Hz), the first and second frequencies are selected to be lower than the frequency of typical power lines in the location of implementation (e.g., 100 Hz in China, 120 Hz in the United States, etc.). Since the frequency spectrum of an object (e.g., a human body) with a normal movement speed is typically concentrated around a low frequency component, even if the object moves at a high speed, a rich low frequency component (e.g., lower than 100 Hz) may be present in the frequency spectrum. This low frequency component may be sufficient to reflect the distance feature of the detected object.

In some embodiments, the second frequency can be selected to be greater than 100 Hz (e.g., in China) or 120 Hz (e.g., in the United States). In order to avoid power line interference, before delivering the sensor from the factory, the accumulation sum SUM_{accum static} of the frequency of the power line interference and the neighboring frequencies thereof when the object is in a static state may be measured. After obtaining the Accumulation Sum Distance Standard Curve (e.g. curve 200), the interference signal contribution amount SUM_{accum}_{_{—}}_{static} can be subtracted from curve 200 to obtain an adjusted Accumulation Sum Distance Standard Curve. During actual detection, the interference signal contribution amount SUM_{accum}_{_{—}}_{static} is subtracted from the calculated accumulation sum SUM_{accum}, and the subtracted result is compared with the adjusted Accumulation Sum Distance Standard Curve, thereby dynamically eliminating the influence of power line interference. This method is also applicable for the influence of GSM cell phone signal interference.

In other embodiments, the upper and lower integration limits can be selected to avoid power line interference. For example, integration of the amplitude of the signal with frequency between 4 Hz and 92 Hz in the outputted spectrum may avoid power line interference. Because the normal movement speed of an object (e.g. a human body in a bathing area) is about 1 meter per second, even if the object moves at a high speed, the frequency spectrum may include rich low frequency components (e.g., lower than 92 Hz). The main components of the signal will not be lost when only the amplitude of the signal with frequency between 4 Hz and 92 Hz in the spectrum is integrated.

Referring now to FIG. 3, a FFT-based microwave detection apparatus 300 is shown, according to an exemplary embodiment. Microwave detection apparatus 300 is shown to include a microwave sensor 302, a signal conditioning device 310, and a digital signal processing device 320. Digital signal processing device 320 is shown to include a sampling and analog-digital converter 322, a FFT device 324, and a movement state determination device 326.

Microwave sensor 302 may detect an object and output a signal which reflects the movement characteristics of the object (e.g., speed, velocity, etc.). In some implementations, the signal output by sensor 302 may have a relatively small amplitude and may contain interference (e.g., “clutter”) signals. In some embodiments, the signal output by sensor 302 may be conditioned. Microwave sensor 302 may output the signal to signal conditioning device 310.

Signal conditioning device 310 is shown to include an amplifier 312 and a band pass filter 314. In some embodiments, amplifier 312 may be a “LMV358” signal amplifier as manufactured by TI Company. Band pass filter 314 may include resistance and capacitance elements. The lower and upper turning frequencies of the band pass filter may be determined according to the movement characteristics (e.g. velocity, movement direction) of the moving object.

Still referring to FIG. 3, the amplified and band pass filtered signal may be sent from signal conditioning device 310 to sampling and analog-digital converter 322. Sampling and analog-digital converter 322 may continuously sample and convert the signal, such that the time domain analog signal is converted into a time domain discrete digital signal. The sampling frequency f may be determined according to the movement characteristics (e.g. velocity, movement direction) of the moving object. Preferably, the sampling frequency f is approximately three times of the upper turning frequency of the band pass filter. Sampling and analog-digital converter 322 may output the time domain discrete digital signal to FFT device 324.

FFT device 324 may perform a Fast Fourier Transform on continuous P time domain discrete digital signals (e.g., a P point FFT) at a certain time interval of Δt. FFT device 324 may obtain a movement spectrum curve of the object as a result of the FFT. The spectrum curve may indicate the distribution of the movement characteristics of the object in the frequency domain. The signal amplitude A may represent the distance between the object and the sensor.

The spectrum of the frequency domain signal output by FFT device 324 may be sent to an integrating unit 328 of movement state determination device 326. Integrating unit 328 may integrate the amplitude A of the signal between the first and second frequencies in the movement spectrum to obtain an integration SumA . Integrating unit 328 may accumulate the integrations SumA of the previous N times (including current time) to obtain an accumulation sum SUM_{accum} Integrating unit 328 may send SUM_{accum} to comparing unit 330.

Comparing unit 330 may compare SUM_{accum} with an Accumulation Sum Distance Standard Curve to obtain a corresponding current distance. The Accumulation Sum Distance Standard Curve may be retrieved from storage 332. As to other preferred embodiments, the working principles thereof are substantially the same as those described according to FIG. 1 and are omitted here for brief purpose.

In some embodiments, after obtaining current distance, microwave detection apparatus 300 can send the distance to another control apparatus. The control apparatus can compare the distance with a threshold value and output a signal according to the comparison result to control the action of bathing equipments. For example, if the distance is smaller than a smallest threshold value, the bathing equipment can be activated or ordered to start operation. If the distance is larger than a largest threshold value, the bathing equipment can be deactivated or ordered to stop operation.

Advantageously, the technical solution offered by the systems and methods of the present invention may be highly accurate. For example, the technical solution of the present invention may be 50% more accurate than traditional microwave detecting devices.

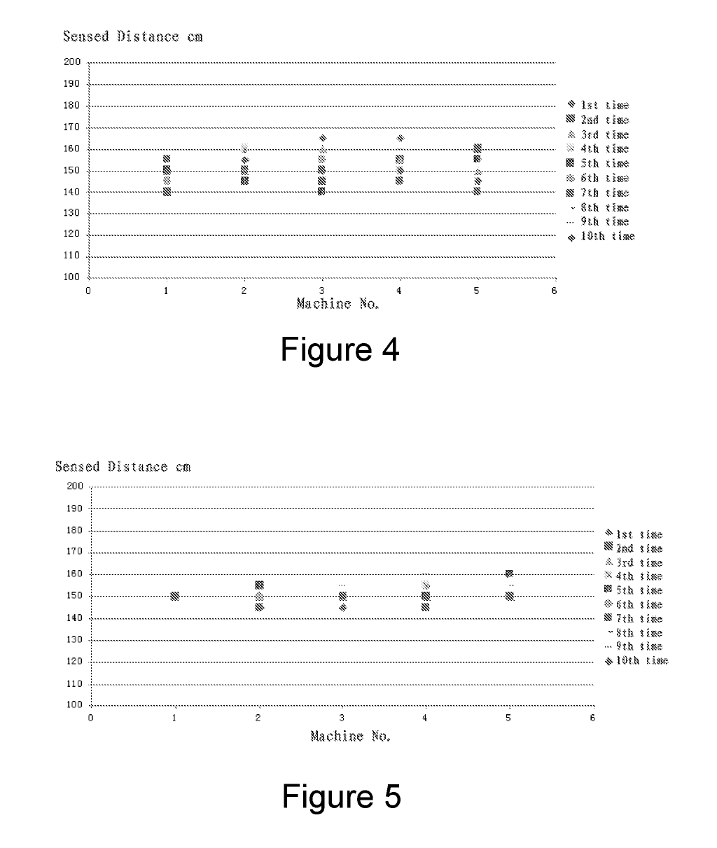

Referring now to FIG. 4 and the following table, Table 1, experimental data associated with a traditional microwave detection device are shown. FIG. 4 graphically illustrates the testing results included in Table 1. The sensed distances of five traditional apparatuses are measured ten times, for each device. For each machine, the positions representing the sensed distances do not overlap and are discrete. Referring specifically to “Machine No. 2,” the sensed distances range from 145 cm to 160 cm, with major fluctuations.

TABLE 1
(Unit: cm)

| | The | The | The | The | The | The | The | The | The | |
|---|---|---|---|---|---|---|---|---|---|---|
| Machine | first | second | third | fourth | fifth | sixth | seventh | eighth | ninth | The tenth |
| No. | time | time | time | time | time | time | time | time | time | time |
| 1 | 150 | 140 | 150 | 155 | 150 | 145 | 155 | 140 | 145 | 150 |
| 2 | 160 | 145 | 150 | 160 | 145 | 150 | 150 | 145 | 150 | 155 |
| 3 | 150 | 145 | 160 | 155 | 140 | 155 | 150 | 140 | 155 | 165 |
| 4 | 165 | 155 | 155 | 150 | 145 | 145 | 145 | 150 | 160 | 150 |
| 5 | 160 | 160 | 150 | 145 | 155 | 140 | 140 | 155 | 145 | 145 |

Referring now to FIG. 5 and the following table, Table 2, experimental data associated with the FFT-based microwave detection apparatus of the present invention (e.g., detection apparatus 300) are shown. FIG. 5 graphically illustrates the testing results included in Table 2. After measuring five apparatus according to the present invention, it is found that the sensed distances are very precise and the sensing accuracy is improved relative to traditional apparatuses. Referring specifically to “Machine No. 1,” each sensed distance for ten measurements is exactly 150 cm (shown as a single point in FIG. 5).

TABLE 2
(Unit: cm)

| | The | The | The | The | The | The | The | The | The | |
|---|---|---|---|---|---|---|---|---|---|---|
| Machine | first | second | third | fourth | fifth | sixth | seventh | eighth | ninth | The tenth |
| No. | time | time | time | time | time | time | time | time | time | time |
| 1 | 150 | 150 | 150 | 150 | 150 | 150 | 150 | 150 | 150 | 150 |
| 2 | 150 | 155 | 150 | 145 | 155 | 150 | 145 | 155 | 150 | 145 |
| 3 | 150 | 150 | 150 | 150 | 150 | 150 | 150 | 150 | 155 | 145 |
| 4 | 155 | 150 | 150 | 155 | 150 | 145 | 145 | 150 | 160 | 150 |
| 5 | 150 | 150 | 150 | 150 | 160 | 150 | 150 | 155 | 150 | 150 |

The above embodiments are intended to illustrate, but not to limit the present invention. Any modifications or amendments without departing from the spirit of the description are included in the present invention and shall fall in to the scope of protection defined by the claims.

What is claimed is:

1. A method for detecting a position of an object relative to a plumbing fixture, the method comprising:
emitting a microwave detection signal toward a moving object, receiving an echo-wave signal reflected from the moving object, and superimposing the microwave detection signal and the echo-wave signal to produce a superimposed time domain signal;
performing a Fast Fourier Transformation on the time domain signal to generate a frequency domain signal;
integrating the frequency domain signal;
actively adjusting a result of the integration by subtracting a predetermined amount from the result, wherein the predetermined amount is at least one of: a volume contribution amount and an interference contribution amount; and
determining a position of the moving object relative to the plumbing fixture by comparing the adjusted integration result with a distance standard curve, wherein the distance standard curve is pre-adjusted to account for the subtraction of the predetermined amount.

2. The method of claim 1, wherein the volume contribution amount is an amount of the integration result attributable to a volume of a static object, and
wherein the interference contribution amount is an amount of the integration sum attributable to at least one of: power line interference and cell phone signal interference.

3. The method of claim 1, wherein integrating the frequency domain signal includes selecting an integration range, wherein the integration range is selected to exclude at least one of: a power line interference frequency and a cell phone signal interference frequency.

4. The method of claim 1, further comprising:
filtering the superimposed time domain signal using a band pass filter having a band pass range, wherein the band pass range is selected based on an estimated movement speed of the moving object,
wherein the Fast Fourier Transformation is performed on the filtered time domain signal.

5. The method of claim 1, further comprising:
performing multiple Fast Fourier Transformations on multiple discrete portions of the time domain signal to generate multiple frequency domain signals;
integrating each of the multiple frequency domain signals to obtain multiple integration sums; and
calculating an accumulation sum by adding the multiple integration sums, wherein the accumulation sum is the result of the integration from which the predetermined amount is subtracted.

6. The method of claim 1, wherein the superimposed time domain signal is an analog signal, the method further comprising:
sampling the time domain analog signal at a predetermined sampling frequency, wherein the sampling frequency is determined according to an estimated movement speed of the moving object; and
converting the time domain analog signal to a discrete time domain digital signal.

7. The method of claim 1, further comprising:
amplifying the superimposed time domain signal prior to performing the Fast Fourier Transformation.

8. The method of claim 1, further comprising:
comparing the determined position of the moving object relative to the plumbing fixture with a threshold value; and
operating the plumbing fixture based on a result of the comparison.

9. A method for detecting a position of an object relative to a plumbing fixture, the method comprising:
emitting a microwave detection signal toward a moving object, the microwave detection signal having an emission frequency, and receiving an echo-wave signal reflected from the moving object, the echo wave signal having an echo frequency;
superimposing the microwave detection signal and the echo-wave signal to produce a superimposed time domain signal having an output frequency defined by a difference between the emission frequency and the echo frequency;
predicting a range of values for the output frequency using a minimum expected movement speed and a maximum expected movement speed of the moving object;
filtering the superimposed time domain signal using a band pass filter, wherein the band pass filter has a lower turning frequency and an upper turning frequency defining a band pass range, wherein the turning frequencies are selected such that the band pass range includes the predicted range of values for the output frequency;
performing a Fast Fourier Transformation on the filtered time domain signal to generate a frequency domain signal; and
determining a position of the moving object relative to the plumbing fixture by integrating the frequency domain signal and comparing a result of the integration with a distance standard curve.

10. The method of claim 9, wherein predicting a range of values for the output frequency includes:
receiving a minimum expected movement speed and a maximum expected movement speed of the moving object;
using a doppler principle to describe the predicted output frequency as a function of the speed of the moving object; and
calculating a minimum predicted output frequency and a maximum predicted output frequency using the doppler principle and the minimum expected movement speed and the maximum expected movement speed respectively.

11. The method of claim 9, wherein the minimum expected movement speed of the moving object is approximately one meter per second and the maximum expected movement speed of the moving object is approximately two meters per second.

12. The method of claim 9, further comprising:
performing multiple Fast Fourier Transformations on multiple discrete portions of the filtered time domain signal to generate multiple frequency domain signals;
integrating each of the multiple frequency domain signals to obtain multiple integration sums; and
calculating an accumulation sum by adding the multiple integration sums, wherein the accumulation sum is the result of the integration used to determine the position of the moving object relative to the plumbing fixture.

13. The method of claim 9, wherein the superimposed time domain signal is an analog signal, the method further comprising:
using the upper turning frequency of the band pass filter to determine a sampling frequency for the time domain analog signal, wherein the sampling frequency is a multiple of the upper turning frequency;
sampling the time domain analog signal at the determined sampling frequency; and
converting the time domain analog signal to a discrete time domain digital signal using samples collected by the sampling.

14. The method of claim 13, wherein the sampling frequency is approximately three times the upper turning frequency.

15. The method of claim 9, further comprising:
amplifying at least one of the superimposed time domain signal and the filtered time domain signal prior to performing the Fast Fourier Transformation.

16. The method of claim 9, further comprising:
comparing the determined position of the moving object relative to the plumbing fixture with a threshold value; and
operating the plumbing fixture based on a result of the comparison.

17. A method for detecting a position of an object relative to a plumbing fixture, the method comprising:
emitting a microwave detection signal toward a moving object, receiving an echo-wave signal reflected from the moving object, and superimposing the microwave detection signal and the echo-wave signal to produce a superimposed time domain signal;
performing a Fast Fourier Transformation on the time domain signal to generate a frequency domain signal;
integrating the frequency domain signal within an integration frequency range, wherein the integration frequency range is selected to exclude at least one of: a power line interference frequency and a cell phone signal interference frequency; and
determining a position of the moving object relative to the plumbing fixture by comparing a result of the integration with a distance standard curve.

18. The method of claim 17, wherein the power line interference frequency is within a range from approximately 100 Hz to approximately 120 Hz, and
wherein the cell phone signal interference frequency is approximately 220 Hz.

19. The method of claim 17, wherein an upper limit of the integration frequency range is no greater than approximately 92 Hz.

20. The method of claim 17, further comprising:
comparing the determined position of the moving object relative to the plumbing fixture with a threshold value; and
operating the plumbing fixture based on a result of the comparison.
